(19) United States
(12) Patent Application Publication
(10) Pub. No.: US 2008/0164886 A1
(43) Pub. Date: Jul. 10, 2008

(54) Inductive Sensor Device Having A Conical Coil Core

(75) Inventor: Thomas Feucht, Wimsheim (DE)

Correspondence Address: CROWELL & MORING LLP;INTELLECTUAL PROPERTY GROUP, P.O. BOX 14300, WASHINGTON, DC, 20044-4300, US

(73) Assignee: Knorr Bremse Systeme fuer Nutzfahrzeuge GmbH, Muenchen (DE)

(21) Appl. No.: 11/952,523

(22) Filed: Dec. 7, 2007

(30) Foreign Application Priority Data
Dec. 8, 2006 (DE) 10 2006 057 917.8

(51) Int. Cl. G01R 27/28

(52) U.S. Cl. 324/654

(57) ABSTRACT

The invention relates to an inductive sensor device (1) having at least one electric coil (4, 16), a coil core (6) being provided which dips into the coil (4, 16) and can be adjusted corresponding to a path or angle to be measured.

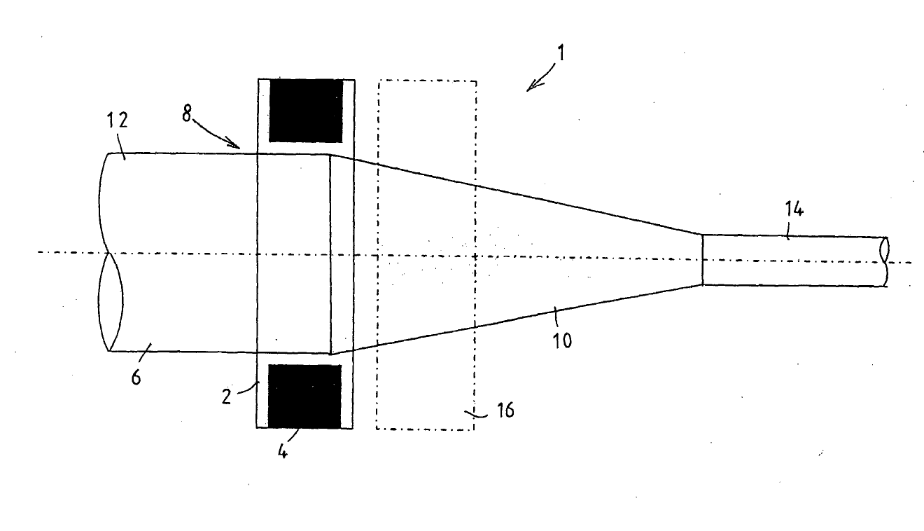

The invention provides that the coil core (6) has a section (10) that tapers, starting from a section (12) of a constant cross-section adjoining on one side, viewed in the longitudinal direction of the coil core, step-by-step or continuously, to a section (14) of a constant cross-section adjoining on the other side. When the measuring path is defined, shorter coils can therefore be used, whereby space is saved.

### STATE OF THE ART

The invention is based on an inductive sensor device having at least one electric coil, a coil core being provided which can be adjusted corresponding to a path or angle to be measured and plunges into the coil, according to the preamble of claim 1.

From the state of the art, so-called plunger-type armature sensors are known, in the case of which the magnetic flux encounters a lower resistance as a result of dipping soft-iron cores into the coil, whereby the inductivity of the coil is measurably increased. The soft-iron core usually has a smooth-cylindrical construction. However, the length of such plunger-type armature sensors, as a rule, considerably exceeds the measuring path.

An inductive sensor device of this type is also known from German Patent Document DE 43 30 540 C1. There, a coil form carrying the coil has a rectangular construction and has a slot-shaped opening in its center, into which an eccentric rotatably disposed plate, which acts as a coil core, can be plunged from the outside. However, the disadvantage of this construction is also the relatively high space requirement.

A typical application of such inductive displacement sensors is the measuring of a pedal travel or angle of rotation of a motor vehicle pedal, particularly of a utility vehicle pedal, especially of a utility vehicle brake pedal in a foot brake module of an electronic braking system. As a function of the rotating position or of the operating travel of the foot pedal, a desired-value signal for the braking force or braking pressure is generated in a microprocessor-based analyzing device, which desired-value signal is processed by a brake control device which generates control signals therefrom for pressure control modules arranged on the output side. An analogous situation applies to the gas and the clutch pedal when the corresponding actuators are controlled electrically.

Since the space in the area of such foot pedal modules, as a rule, is very limited, space-saving solutions are desirable. However, if, for reducing the space requirement, only the length of the coil cores were to be decreased, a shorter measuring path and therefore a lower resolution or a lower sensitivity of such an inductive sensor device would be obtained, which does not seem to be desirable with respect to the proportioning capacity of the respectively operated function (gas, brake, clutch).

It is therefore an object of the invention to further develop an inductive sensor device of the initially mentioned type such that it has smaller dimensions and nevertheless has a relatively long measuring path.

According to the invention, this object is achieved by the characteristics of claim 1.

### Advantages of the Invention

The invention is based on the idea of not constructing the coil core cylindrically as according to the state of the art but such that it has a section that tapers, starting from a section of a constant cross-section adjoining on one side, viewed in the longitudinal direction of the coil core, step-by-step or continuously, to a section of a constant cross-section adjoining on the other side.

Because of the step-by-step or continuous tapering of the cross-section, as a function of the plunging depth of the coil core into the coil, a more intensively changing fraction of its volume is detected by the magnetic field than in the case of smoothly cylindrical coil cores. While the length of the coil cores is the same, the construction according to the invention therefore achieves a longer measuring path and thus a higher resolution and sensitivity. Using the same measuring path as in the prior art as a scale, a decreased length of the coil and of the coil core therefore becomes possible, whereby the space requirement of the inductive sensor device is reduced, and an application as a path sensor or angle sensor therefore is particularly advantageous in the case of foot pedals in vehicles.

In order to achieve a sensitivity and linearity sufficient for a measurement, it is a prerequisite that the coil form is sufficiently detected by the lines of magnetic flux of the magnetic field, which a person skilled in the art defines by a suitable adaptation of the geometries and coil turns, etc.

By means of the measures indicated in the subclaims, further developments and improvements of the invention indicated in the independent claim can be obtained.

Particularly preferably, the cross-section of the coil core is cylindrical and the tapering is conical. This results in a very simple production of the coil core.

Because of the reduction of the coil length, particularly several coils can be arranged in series behind one another, at least one coil representing a redundant coil with respect to another coil. This arrangement ensures the functioning of the inductive sensor device also when the other coil is failing. This is significant particularly in the case of safety relevant applications, such as an inductive sensor device of a brake pedal, where the measuring signal forms the basis of the brake application. Because the inductive sensor device has a short construction, an additional redundant coil arranged behind or in front of a coil can be provided without an excessive increase of its length.

### DRAWINGS

An embodiment of the invention is illustrated in the drawing and will be explained in detail in the following description. In the drawing, the single FIGURE is a cross-sectional representation of an inductive sensor device according to a preferred embodiment of the invention.

### DESCRIPTION OF THE EMBODIMENT

The FIGURE illustrates an embodiment of an inductive sensor device 1 according to the invention. In this case, the measuring principle is based on the measurement of the change of the inductivity of an electric coil 4 wound onto a coil form 2, by inserting a coil core 6 into a central coil opening 8 of the coil form 2 and thereby into the lines of electric flux of the electric field generated by it.

The inductivity of such a coil 2 is computed as follows according to Equation (1):

$$L = \frac{{N}^{2} \cdot μ \cdot A}{s} \qquad ( 1 )$$

wherein
N is the number of turns in the winding of the coil 4,
s is the path length of the lines of magnetic flux,
A is the surface penetrated by the lines of magnetic flux,

μ is the permeability of the material of the coil core 6.

The inductivity can therefore be changed by the insertion of material of different permeabilities in the magnetic circuit. The invention is first based on the idea of linearly displacing the coil core 6 assigned to the coil 4 and arranged in the coil opening 8 in this coil opening 8. The coil core 6 preferably consists of a ferromagnetic material or of aluminum.

A change of the inductivity of the coil 4 as a measurement 4 of a change of a path or angle is then achieved in that the coil core 6 interacts with an object whose rotating position or path position is to be measured, such that, when the rotating position or the path position of the object is changed, a different fraction of the volume of the coil core 6 is detected by the magnetic field. This means that, as a result of a change of the axial position of the coil core 6 relative to the coil 4, a change of the inductivity of the coil 4 as a measurement of a change of the rotating position or path position of the object is caused. The permeability of ferromagnetic materials, such as iron, cobalt or nickel is significantly greater than 1, so that the magnetic field is considerably intensified when such a coil core 6 is detected by the lines of magnetic flux.

The coil core 6 has a section 10 that tapers, starting from a section 12 of a constant larger cross-section adjoining on one side, viewed in the longitudinal direction of the coil core, step-by-step or continuously, to a section 14 of a constant smaller cross-section adjoining on the other side. Particularly preferably, the cross-section of the coil core 6 has a cylindrical construction, and the tapered section 10 has a conical construction. In this case, the coil core 6 preferably projects through the coil form opening 8, a change of the inductivity of the coil occurring when the cross-section of the coil core 6 situated within the coil form opening 8 changes as a result of an axial linear movement of the coil core 6, which takes place in the area of the conical section 10.

Because of the resulting reduction of the length of the coil 4 or of the coil form 2, while the measuring path is simultaneously large, particularly several coils 4, 16 can be arranged in series behind one another, at least one coil 16 being a redundant coil with respect to another coil 4. As a result, the functioning of the inductive sensor device 1 is also ensured when the other coil 4 is failing. In the present case, two coils 4, 16 are provided into whose coil form openings 8 the coil core 6 dips 6 or penetrates the latter, and of which one coil 16 represents a coil which is redundant with respect to the other coil 4.

### LIST OF REFERENCE NUMBERS

1 sensor device
2 coil form
4 coil
6 coil core
8 coil form opening
10 section
12 section
14 section
16 coil

1-5. (canceled)

6. An inductive sensor device, comprising:
at least one electric coil;
a coil core operatively configured to dip into the electric coil and to be adjustable in accordance with a path or angle to be measured;
wherein the coil core comprises a tapered section that tapers in a longitudinal direction of the coil core at one end from a section having a constant cross-section down to another section at the other end having a different constant cross-section.

7. The inductive sensor device according to claim 6, wherein the tapered section tapers in one of a continuous and step-by-step manner.

8. The inductive sensor device according to claim 6, wherein the cross-section of the coil core has a cylindrical construction, and the tapered section has a conical construction.

9. The inductive sensor device according to claim 7, wherein the cross-section of the coil core has a cylindrical construction, and the tapered section has a conical construction.

10. The inductive sensor device according to claim 6, further comprising at least one additional electric coil arranged in series behind the electric coil, wherein at least one of the electric coils is redundant with respect to another electric coil.

11. The inductive sensor device according to claim 7, further comprising at least one additional electric coil arranged in series behind the electric coil, wherein at least one of the electric coils is redundant with respect to another electric coil.

12. The inductive sensor device according to claim 8, further comprising at least one additional electric coil arranged in series behind the electric coil, wherein at least one of the electric coils is redundant with respect to another electric coil.

13. The inductive sensor device according to claim 6, wherein the sensor device is operatively configured to measure a pedal position of a vehicle pedal of a vehicle.

14. The inductive sensor device according to claim 10, wherein the sensor device is operatively configured to measure a pedal position of a vehicle pedal of a vehicle.

15. The inductive sensor device according to claim 6, wherein the coil core comprises one of a ferromagnetic material and an aluminum material.

16. The inductive sensor device according to claim 7, wherein the coil core comprises one of a ferromagnetic material and an aluminum material.

17. The inductive sensor device according to claim 8, wherein the coil core comprises one of a ferromagnetic material and an aluminum material.

18. The inductive sensor device according to claim 10, wherein the coil core comprises one of a ferromagnetic material and an aluminum material.
